(19) United States
(12) Patent Application Publication
(10) Pub. No.: US 2026/0322299 A1
(43) Pub. Date: Oct. 15, 2026

(54) METHOD FOR OPERATING AN ELECTRIC MACHINE

(71) Applicant: Brose Fahrzeugteile SE & Co. Kommanditgesellschaft, Würzburg, Würzburg (DE)

(72) Inventor: Johannes SCHWARZKOPF, Marktheidenfeld (DE)

(21) Appl. No.: 19/101,273

(22) PCT Filed: Aug. 8, 2023
(86) PCT No.: PCT/EP2023/071883

§ 371 Date: Feb. 28, 2025

(30) Foreign Application Priority Data
Aug. 10, 2022 (DE) 10 2022 208 335.0

(51) Int. Cl. H02P 21/26; G01R 31/34; H02P 21/34

(52) U.S. Cl. CPC H02P 21/26; G01R 31/34; H02P 21/34

(57) ABSTRACT

A method operates an electric machine having a brushless electric motor containing a stator, a rotor, and a closed-loop control unit for sensorless field-oriented open-loop control and/or closed-loop control of the electric motor in a d-q reference system which is fixed with respect to the rotor and with a d axis and a q axis. The electric motor is subjected to open-loop and/or closed-loop control at the start of operation based on an estimated motor position. A test signal is produced to determine a deviation between an actual motor position and the estimated motor position. The test signal is fed into the d axis. The test signal is used for determining a compensation signal such that, when the compensation signal is fed into the q axis, a change in torque of the electric motor is reduced due to the test signal. The compensation signal is fed into the q axis.

The invention relates to a method for operating an electric machine, having a brushless electric motor with a stator and with a rotor, and a control unit for sensorless field-oriented open-loop and/or closed-loop control of the electric motor in a d/q-coordinate system which is fixed with respect to the rotor. The invention furthermore relates to an electric machine for carrying out the method and also a software on a data carrier.

Electromotively driven or operated adjustment systems as motor vehicle components, such as for example window regulators, seat adjusters, door and sunroof drives or radiator fan drives and pumps and interior fans typically have an electric drive with an open-loop controlled electric motor. So-called brushless electric motors (brushless direct current motor, BLDC motor), in which the wear-prone brush elements of a rigid (mechanical) commutator are replaced by an electronic commutation of the motor current, are being used increasingly often for such electromotive drives.

Electromotive drives for motor vehicles are generally fed by a (high-voltage) battery as vehicle-internal energy storage device, from which the electric motor is supplied with electrical energy in the form of a direct current (DC voltage). To convert the direct current into motor current, a power converter (power inverter, inverter) is connected between the battery and the electric motor in a suitable manner. The power converter has a bridge circuit which is supplied with the direct current or DC voltage of the energy storage device via an electrical intermediate circuit. The motor current is generated as a multi-phase output current by a pulsewidth-modulated (PWM) control or closed-loop control of semiconductor switches of the bridge circuit. The semiconductor switches are switched between an on and an off state in a clocked manner by the pulses of the PWM signals.

In operation, the bridge circuit feeds the electric motor current (three-phase current) into the stator coils of the electric motor, which electric motor current as a consequence generates a rotating magnetic field that rotates in relation to the stator. The rotor of the electric motor here suitably has a number of permanent magnets, wherein due to the interaction of the permanent magnets with the rotating field, a resultant torque is generated, which sets the rotor rotating.

The phases of the three-phase current that is generated and the associated rotating field are referred to as (motor) phases. In a figurative sense, this is also understood to mean the stator coils (phase winding) with the associated connecting lines (phase end), which are assigned to such a phase in each case. The phases are for example connected to one another in a star point of a star connection.

For efficient operation, it is necessary that the phases are supplied with current at the right time. To this end, a closed-loop vector control, also referred to as a field-oriented control (field-oriented control, FOC), is for example possible. In such a field-oriented control or FOC, the three-phase current is identified as two orthogonal components which can be visualized using a current space vector. One component (direct component) defines the magnetic flux of the motor, the other the torque (quadrature current).

The field-oriented control controls the three-phase current in a closed-loop manner in a d-q reference system of the electric motor. Ideally, the current space vector is fixed with respect to the rotor in terms of magnitude and direction (quadrature), that is to say is independent of the rotation. As the current space vector is static in the d-q reference system, the closed-loop current control takes place on the basis of direct current signals. This isolates the closed-loop controller from the winding currents and voltages, which vary over time, and therefore eliminates the limitation of the controller frequency response and the phase shift to the motor torque and the speed.

The electric motor here has an assigned open-loop motor control which determines the corresponding current component set-point values from the flux and torque set-point values which are specified by a closed-loop speed control. The motor or phase currents are transformed to the d-q reference system in this case.

To ensure that the phases are supplied with current at the right time, an accurate determination of the relative position of rotor and stator is necessary. The rotor position for position determination is for example ascertained by means of additional rotary encoders, such as a Hall effect sensor for example. Rotary encoders of this type are cost-intensive however, which is why position determination should preferably take place in a sensorless manner.

Sensorless position determination is based for example on the detection of induced current and/or voltage signals owing to the back electromotive force (back EMF) which the rotating permanent magnets induce in the phase windings. The induced back EMF signals are proportional to the rotor speed, as a result of which only little or no information for position determination is disadvantageously available for the open-loop motor control in the case of low speeds or in the case of standstill of the electric motor. In particular, the signal-to-noise ratio is reduced at low speeds. A restriction of this type also exists for flux-based sensorless measuring methods. As a result, position determination or position detection is generally not possible below a threshold speed, as a result of which a safe and reliable operation of the electric motor is disadvantageously made more difficult, particularly during start-up from standstill or during operation at low speed.

In this case, it is for example possible to estimate the rotor position close to the (motor) standstill and to control the electric motor on the basis of the estimation. In order to determine a deviation between the estimated position and the actual position and subsequently to correct this, a test signal or test pulse is for example fed into the presumed d axis. This test signal may however lead to torque ripple of the electric motor, as a result of which particular undesirable acoustic impairments may occur.

These acoustic impairments are generally only present temporarily during start-up or during low motor speeds of the electric motor, so that these acoustic impairments can often be accepted. Alternatively, the acoustic influence of the test signal is reduced by mechanical measures. This is connected with additional costs, however.

The invention is based on the object of specifying a particularly suitable method for operating an electric machine. In particular, a reliable sensorless open-loop and/or closed-loop control of motor operation should also be enabled at low speeds. Furthermore, motor operation for which the noise is reduced as much as possible should be enabled. The invention is furthermore based on the object of specifying a particularly suitable electric machine and a particularly suitable software on a data carrier.

The advantages and embodiments listed with regard to the method are also correspondingly transferable to the electric machine and/or the software and vice versa. The conjunction “and/or” is to be understood in such a manner here and in the following that the features linked by means of this conjunction may be formed both together and as alternatives to one another.

The method according to the invention is provided for operating an electric machine and is also suitable and configured for this. Insofar as method steps are described in the following, advantageous embodiments for the electric machine can be gathered in particular from this electric machine being designed to execute one or more of these method steps.

According to the method, a control unit is here provided for generating an open-loop control variable for an electric motor of the electric machine. The electric motor is in particular realized here as a brushless electric motor having a multi-phase, particularly at least three-phase, rotating-field winding. The control unit generates the open-loop control variable for motor control on the basis of an actual current value (input currents U, V, W) and an actual position value (rotor position). The input currents for the motor phases are to be understood in particular here as the actual current value, wherein the actual position value in particular specifies a mechanical position or an electrical position of the rotor of the electric motor. The mechanical position (mechanical angle) here describes the absolute mechanical position of the rotor in relation to the stator in particular, wherein the electrical position (electrical angle) in particular describes the position value that is decisive for the commutation of the motor current. The electrical position here specifies the phase position of a current vector for commutating the electric motor in particular. The actual position value preferably corresponds to the electrical rotor position.

The motor operation of the electric motor is controlled in an open- and/or closed-loop manner by a field-oriented control (FOC) of the control unit. Here a motor or phase current of the electric motor as actual current value is controlled in a closed-loop manner by means of a closed-loop current control in a d-q reference system (d/q coordinate system) having a DC voltage component along a d axis and a quadrature current along a q axis. The electric machine or the electric motor is realized in a sensorless manner, this means that no position sensor is provided for direct detection of the rotor position. The actual position value is therefore determined in a sensorless manner for example on the basis of a back EMF of the electric motor.

At the start of operation, that is to say for example when the electric motor is at a standstill, during which there is in particular still not sufficient back EMF for determining the actual position value, the electric motor is controlled in an open-loop and/or closed-loop manner according to the method on the basis of an estimated motor position. In other words, an estimated actual position value is used initially for the FOC. Here and in the following, “estimation” or “estimate” is understood to mean an approximate determination of the motor position or the actual position value by evaluating the back EMF, for example by visual inspection, pre-characterized measurements, stored tables or characteristic curves, or by means of statistical mathematical methods. The estimated actual position value may in this case also be a stored starting value.

To check and adapt the position estimation, a test signal or test pulse is generated, by means of which a deviation between an actual motor position (true actual position value) and the estimated motor position (estimated actual position value) is generated. This test signal is fed into the (estimated) d axis of the electric motor.

According to the invention, a compensation signal is generated in addition to the test signal and fed into the (estimated) q axis of the electric motor. The compensation signal is determined on the basis of the test signal here in such a manner that when the compensation signal is fed into the q axis, a torque change of the electric motor owing to the test signal is reduced or compensated. As a result, the torque ripple due to the test signal is compensated by a further control signal (compensation signal). As a consequence, the acoustics of the electric motor are improved, particularly during start-up. As a result, a particularly suitable method for operating an electric machine is realized.

Contrary to a conventional control, in the invention, not only the DC voltage component, but also the quadrature component is controlled. These values or a motor response to these values can for example be measured well by means of the phase current.

Preferably, the torque change of the electric motor owing to the test signal is reduced as completely as possible by the compensation signal, so that a particularly quiet start of the electric machine is enabled. As a result, user comfort is improved, particularly in the case of use of the electric machine as an adjustment drive in a vehicle interior of a motor vehicle.

In an expedient development, a motor response to the test signal and the compensation signal, for example in the form of a current in the q axis is detected and used for determining a motor position. The test signal is used for checking the position estimation. The current in the q direction is dependent on the deviation from the estimated motor position, if no error exists between the estimated and real position, that is to say if there is no deviation between the actual motor position and the estimated motor position, no current is generated in the stator windings of the electric motor for example. The induced current can be detected as motor response for example by means of a current measuring instrument, particularly by means of a shunt resistor. Due to the test signal, an open-loop and/or closed-loop control of the estimated motor position is also enabled at low motor speeds, wherein the compensation signal ensures that no torque ripples occur in this case. The estimated motor position can therefore be adapted iteratively or successively to the actual motor position. The method is preferably carried out until a further sensorless method (particularly on the basis of an EMF evaluation) reliably takes over the position determination. The estimated speed can be used here as a criterion to change or switch between the methods.

The invention here takes the following formula for the torque of the electric motor as a starting point:

$$M = \frac{3}{2} * p * ( Ψ * {i}_{q} + ( {L}_{d} - {L}_{q} ) * {i}_{d} * {i}_{q} ) ,$$

wherein p is the number of pairs of poles of the electric motor, Ψ is the magnetic flux, i_{q} and i_{d} are the currents along the q and d axes respectively, and L_{d} and L_{q} are the inductance values of the stator (that is to say the stator coils/the stator winding) along the q and d axes respectively.

At the operating point, the following applies here

$$\frac{δ M}{{δ i}_{d}} = \frac{3}{2} p ( {L}_{d} - {L}_{q} ) {i}_{q}$$

$$\frac{δ M}{{δ i}_{q}} = \frac{3}{2} p ( Ψ + ( {L}_{d} - {L}_{q} ) {i}_{d} )$$

In order to reduce the disruptive influences of the test signal, that is to say the torque ripple, it is therefore necessary that the torque change ΔM for a change of the currents Δi_{q} and Δi_{d} is zero:

$$Δ M = \frac{δ M}{δ {i}_{d}} Δ {i}_{d} + \frac{δ M}{δ {i}_{q}} Δ {i}_{q} = 0$$

$$0 = \frac{3}{2} p ( {L}_{d} - {L}_{q} ) {i}_{q} {Δ i}_{d} + \frac{3}{2} p ( Ψ + ( {L}_{d} - {L}_{q} ) {i}_{d} {Δ i}_{q}$$

Thus, the resultant relationship between the current changes Δi_{q}/Δi_{d} is

$$\frac{Δ {i}_{q}}{Δ {i}_{d}} = - \frac{( {L}_{d} - {L}_{q} ) {i}_{q}}{Ψ + ( {L}_{d} - {L}_{q} ) {i}_{d}} = k$$

wherein k is a compensation factor.

For the FOC, the corresponding voltages u_{d} and u_{q} are typically controlled in a closed-loop manner. The currents i_{d} and i_{q} are dependent on u_{d} and u_{q} here, so, with a Laplace transformation approach, the following equation results:

$$[ \begin{matrix}Δ {i}_{d} \\ Δ {i}_{q}\end{matrix} ] = \frac{1}{{F}_{N} ( s )} [ \begin{matrix}{F}_{dd} ( s ) & {F}_{qd} ( s ) \\ {F}_{dq} ( s ) & {F}_{qq} ( s )\end{matrix} ] [ \begin{matrix}{Δ u}_{d} \\ {Δ u}_{q}\end{matrix} ]$$

wherein s is the Laplace transformation parameter, F_{N} is a normalization factor and F_{dd}, F_{qd}, F_{dq}, F_{qq} are the transfer matrix components.

For the boundary condition

$$Δ M = 0$$

the following results

$$k * {F}_{dd} ( s ) * Δ {u}_{d} + k * {F}_{qd} ( s ) * Δ {u}_{q} = {F}_{dq} ( s ) * Δ {u}_{d} + {F}_{qq} ( s ) * {Δ u}_{q}$$

$$( k * {F}_{qd} ( s ) - {F}_{qq} ( s ) ) * Δ {u}_{q} = ( {F}_{dq} ( s ) - k * {F}_{dd} ( s ) ) * {Δ u}_{q}$$

$${Δ u}_{q} = \frac{{F}_{dq} ( s ) - k * {F}_{dd} ( s )}{k * {F}_{qd} ( s ) - {F}_{qq} ( s )} Δ {u}_{d}$$

The normalization factor F_{N} and the transfer matrix components F_{dd}, F_{qd}, F_{dq}, F_{qq} are identifiable on the basis of a motor model. Which motor model is used here is initially inconsequential in this case. For different electric motors, different motor models are used under certain circumstances. For example, a d-q motor model is used here, as is explained in more detail below in the description of the figures (FIG. 5). The following results for such a motor model

$$[ \begin{matrix}Δ {i}_{d} \\ Δ {i}_{q}\end{matrix} ] = \frac{1}{{L}_{q} {L}_{d} {s}^{2} + {R}_{S} ( {L}_{d} + {L}_{q} ) s + {R}_{s}^{2} + {ω}_{e l}^{2} {L}_{q} {L}_{d}} [ \begin{matrix}{R}_{S} + {L}_{q} s & {ω}_{e l} {L}_{q} \\ - {ω}_{el} {L}_{d} & {R}_{S} + {L}_{d} s\end{matrix} ] [ \begin{matrix}{Δ u}_{d} \\ {Δ u}_{q}\end{matrix} ]$$

$$k * ( {R}_{S} + {L}_{q} s ) * {Δ u}_{d} + k * {ω}_{e l} {L}_{q} * {Δ u}_{q} = {ω}_{e l} {L}_{d} * {Δ u}_{d} - ( {R}_{S} + {L}_{d} s ) * Δ {u}_{q}$$

In a suitable embodiment, the compensation signal Δu_{q} is determined on the basis of the formula

$${Δ u}_{q} = \frac{{ω}_{e l} {L}_{d} - k * ( {R}_{S} + {L}_{q} s )}{k * {ω}_{e l} {L}_{q} + ( {R}_{S} + {L}_{d} s )} {Δ u}_{q}$$

Here, Δu_{d} is the test signal, ωₑₗ is the (rotational) frequency of the rotor, L_{d} and L_{q} are the inductance values of the stator along the d and q axes respectively, R_{S} is the ohmic resistance of the stator (the stator coils/stator winding), s is the Laplace transformation parameter, and k is the compensation factor.

In an expedient development, a simplified calculation of the compensation signal Δu_{q} is used to reduce the computation outlay.

For small rotor frequencies (ωₑₗ~0 kHz), as exist for example in the case of start-up from standstill, the above formula can be approximated with

$$Δ {u}_{q} ≅ \frac{- k * ( {R}_{S} + {L}_{q} s )}{( {R}_{S} + {L}_{d} s )} {Δ u}_{d}$$

If R_{S} can additionally be disregarded, the following results:

$$Δ {u}_{q} ≅ \frac{- k * {L}_{q}}{{L}_{d}} {Δ u}_{d}$$

If however, R_{S} but not ωₑₗ can be disregarded, the following results:

$$Δ {u}_{q} ≅ \frac{{ω}_{el} {L}_{d} - k * {L}_{q} s}{k * {ω}_{el} {L}_{q} + {L}_{d} s} Δ {u}_{d}$$

wherein Δu_{q} is the compensation signal, Δu_{d} is the test signal, ωₑₗ is the frequency of the rotor, L_{d} and L_{q} are the inductance values of the stator along the d and q axes respectively, s is the Laplace transformation parameter, and k is the compensation factor.

In an advantageous embodiment, the compensation factor k is determined on the basis of the formula

$$\frac{Δ {i}_{q}}{Δ {i}_{d}} = - \frac{( {L}_{d} - {L}_{q} ) {i}_{q}}{Ψ + ( {L}_{d} - {L}_{q} ) {i}_{d}} = k$$

To simplify the calculation and therefore to reduce the computation outlay, a simplified proportionality calculation can be used. The above proportionality calculation can be approximated for large magnetic fluxes Ψ>>(L_{d}−L_{q})i_{d} using

$$k ≅ - \frac{( {L}_{d} - {L}_{q} )}{Ψ} {i}_{q}$$

For a particularly resource-saving determination of the compensation signal, which has reduced computation outlay, the simplified calculations of the computation signal Δu_{q} and the proportionality calculation can be combined. In a suitable embodiment, the following applies for Ψ>>(L_{d}−L_{q})i_{d} with a simultaneous disregarding of the influence of R_{S} and ωₑₗ:

$$Δ {u}_{q} ≅ \frac{( {L}_{d} - {L}_{q} ) * {L}_{q}}{Ψ * {L}_{d}} Δ {u}_{d}$$

wherein Δu_{q} is the compensation signal, Δu_{d} is the test signal, Ψ is the magnetic flux, and L_{d}/L_{q} is the inductance value of the stator along the d/q axis.

In a preferred development, a sinus voltage with a constant frequency is used as test signal. In the calculation of the compensation signal, the Laplace transformation parameter s can therefore be replaced by jω_{ud}, wherein j is the imaginary unit, and ω_{ud} is the frequency of the test signal. The following therefore results

$$Δ {u}_{q} = \frac{{ω}_{el} {L}_{d} - k * ( {R}_{S} + {L}_{q} j {ω}_{Ud} )}{k * {ω}_{el} {L}_{q} + ( {R}_{S} + {L}_{d} j {ω}_{Ud} )} Δ {u}_{d}$$

As before, the simplifications Ψ>>(L_{d}−L_{q})i_{d} and/or the disregarding of R_{S} and ωₑₗ can be used to reduce the computation outlay.

If the test signal is a sinus voltage, then the compensation signal is also a sinus voltage. The amplitude and phase value can also be stored in a table here for example and used. These values can be ascertained by means of the equations that are presented. Alternatively however, they can also be ascertained empirically (e.g. with the aid of an acoustic measurement). The table values can for example be created and used depending on the temperature, the estimated speed or the estimated load.

The electric machine according to the invention is for example realized as an adjustment drive in a motor vehicle. The electric machine in this case has a brushless electric motor with a stator and with a rotor. The electric machine furthermore has a control unit for sensorless field-oriented open-loop and/or closed-loop control of the electric motor. The control unit is for example coupled with a controller or integrated into the same.

Here, the controller is generally set up—in terms of programming and/or circuitry—to carry out the previously described method according to the invention. The controller is therefore actually set up to estimate an initial motor position, to generate a test signal and feed it into the estimated d axis, and on the basis of the test signal, to determine a compensation signal and feed it into the q axis.

In a preferred embodiment, the controller is, at least at its core, formed by a microcontroller with a processor and a data memory, in which the functionality for carrying out the method according to the invention is implemented programmatically in the form of an operating software (firmware), so that the method—possibly in interaction with a device user—is carried out automatically when the operating software executes in the microcontroller. In the context of the invention, the controller can however alternatively also be formed by a non-programmable electronic component, such as an application specific integrated circuit (ASIC) or by an FPGA (field programmable gate array) for example, in which the functionality for carrying out the method according to the invention is implemented using circuitry means.

An additional or further aspect of the invention is provided by a software on a medium or data carrier for carrying out or executing the previously described method. This means that the software is stored on a data carrier and provided for executing the previously described method and is suitable and configured for that. In particular, the software is a computer program product comprising commands which, during the execution of the program by a computer, cause this computer to execute the above-described method.

As a result, a software that is particularly suitable for the operation of an electric machine is realized, using which the functionality for carrying out the method according to the invention is implemented programmatically. The software is therefore an operating software (firmware) in particular, wherein the data carrier is a data memory of the controller for example.

Exemplary embodiments of the invention are explained in more detail in the following with reference to a drawing. In the figures:

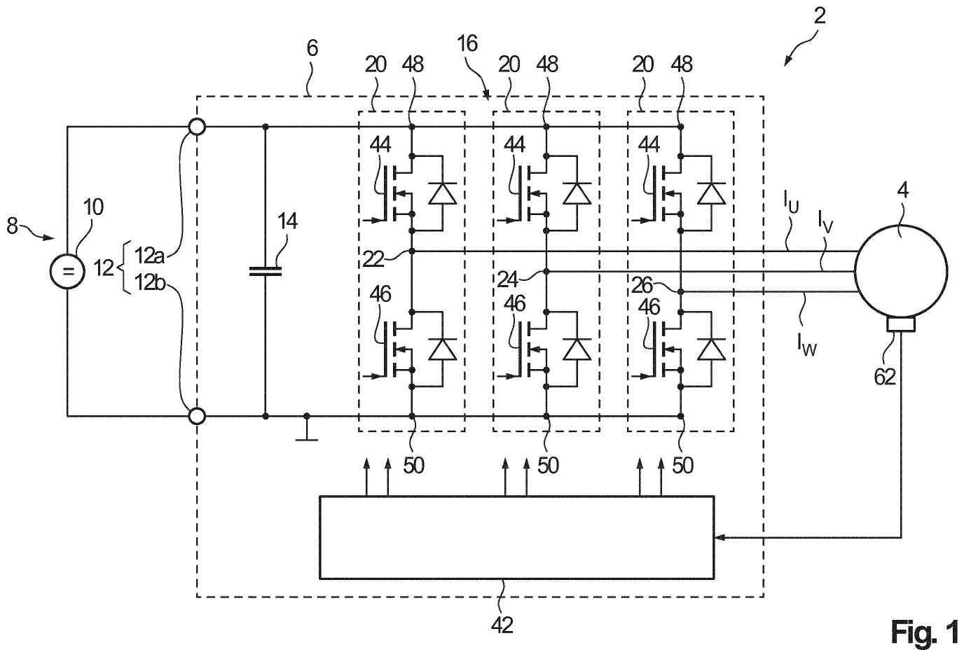

FIG. 1 shows an electric machine with a current source and with an electric motor and also with a power converter that is connected therebetween,

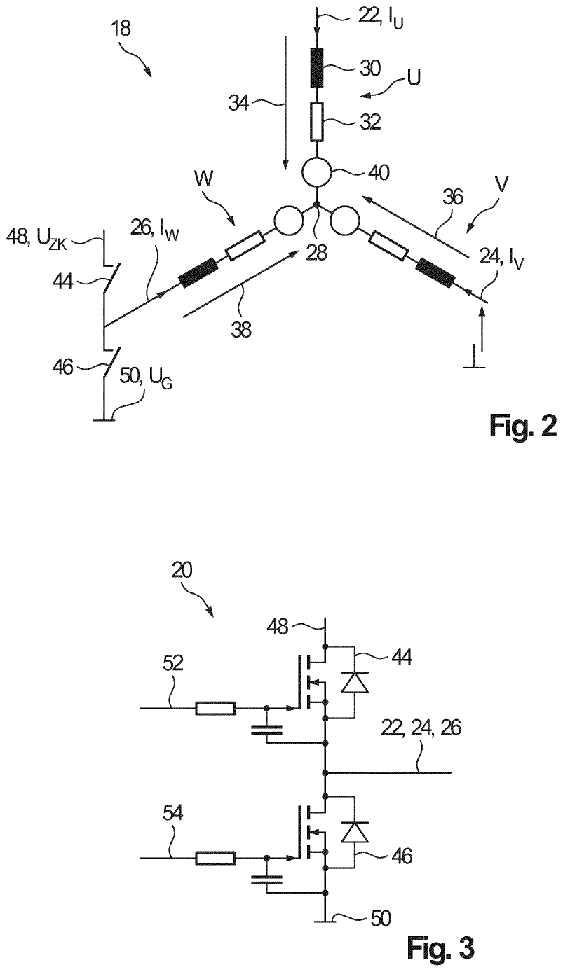

FIG. 2 shows three phase windings of a three-phase electric motor of the machine in star connection,

FIG. 3 shows a bridge module of the power converter for controlling a phase winding of the electric motor,

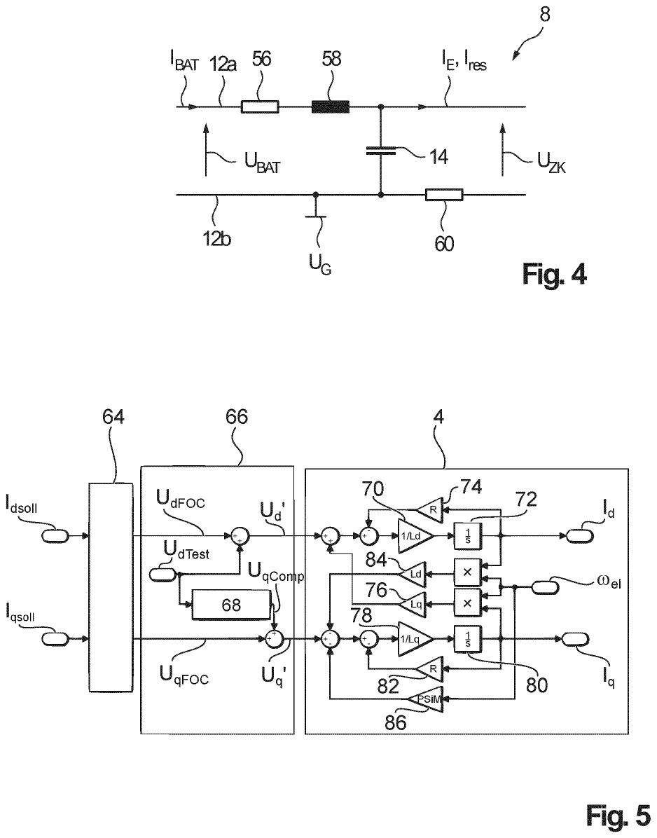

FIG. 4 shows an equivalent circuit diagram for the current source, and

FIG. 5 shows a block diagram for a field-oriented control of the electric motor.

The invention is explained by way of example in the following on the basis of a drive with a B6 circuit. The invention can however also be applied to other arrangements.

Mutually corresponding parts and variables are always provided with the same reference signs in all figures.

FIG. 1 shows an electric machine 2 for an electromotive drive of a vehicle, which is not illustrated in any more detail, for example a motor vehicle or a bicycle that is or can be electrically driven (e-bike). The machine 2 comprises a three-phase brushless electric motor 4 here, which is connected by means of a power converter (frequency converter, power inverter) 6 to a current source (voltage supply) 8. The current source 8 in this exemplary embodiment comprises a vehicle-internal energy storage device in the form of a (motor vehicle) battery 10 and also an (DC voltage) intermediate circuit 12 which is connected to the same and which extends at least partly into the power converter 6.

The intermediate circuit 12 is essentially formed by an outgoing line 12a and a return line 12b, by means of which the power converter 6 is connected to the battery 10. The lines 12a and 12b are guided at least partly into the power converter 6, in which an intermediate-circuit capacitor 14 and a bridge circuit 16 are interconnected between these lines.

In operation of the machine 2, an input current I_{E} that is supplied to the bridge circuit 16 is converted into a three-phase output current (motor current, three-phase current) I_{U}, I_{V}, I_{W} for the three phases U, V, W of the electric motor 4. The output currents I_{U}, I_{V}, I_{W} which are also referred to as phase currents in the following are carried to the corresponding phases (windings) U, V, W (FIG. 2) of a stator which is not illustrated in any more detail.

A star connection 18 of the three phase windings U, V, W is illustrated in FIG. 2. The phase windings U, V and W are guided using one (phase) end 22, 24, 26 in each case to a respective bridge module 20 (FIG. 3) of the bridge circuit 16, and interconnected with one another using the respective opposite end in a star point 28 as common connection terminal. In the illustration of FIG. 2, the phase windings U, V and W are in each case shown by means of an equivalent circuit diagram in the form of an inductor 30 and an ohmic resistor 32 as well as a respective voltage drop 34, 36, 38. The voltage 34, 36, 38 which drops across the phase winding U, V, W in each case is represented schematically by arrows and results from the sum of the voltage drops because of the inductor 30 and the ohmic resistor 32 as well as the induced voltage 40. The voltage 40 (electromagnetic force, EMF) that is induced by a movement of a rotor of the electric motor 4 is illustrated by means of a circle in FIG. 2.

The control of the star connection 18 takes place by means of the bridge circuit 16. The bridge circuit 16 is realized with the bridge modules 20 in particular as a B6 circuit. In this embodiment, switching takes place in operation at each of the phase windings U, V, W in a clocked manner at high switching frequency between a high (DC) voltage level of the supply line 12a and a low voltage level of the return line 12b. The high voltage level here is in particular an intermediate circuit voltage U_{ZK} of the intermediate circuit 12, wherein the low voltage level is preferably a ground potential U_{G}. This clocked control is realized as a PWM control—illustrated by means of arrows in FIG. 1—by a controller 42, using which an open-loop and/or closed-loop control of the speed, the output and the direction of rotation of the electric motor 4 is possible.

The bridge modules 20 in each case comprise two semiconductor switches 44 and 46 which are illustrated in FIG. 2 merely schematically and by way of example for the phase W. The bridge module 20 is on one side connected using a potential terminal 48 to the supply line 12a and thus to the intermediate circuit voltage U_{ZK}. On the other side, the bridge module 20 is contacted using a second potential terminal 50 to the return line 12b and thus to the ground potential U_{G}. By means of the semiconductor switches 44, 46, the respective phase end 22, 24, 26 of the phase U, V, W can be connected either to the intermediate circuit voltage U_{ZK} or to the ground potential U_{G}. If the semiconductor switch 44 is closed (conductive) and the semiconductor switch 46 is opened (non-conductive, off), then the phase end 22, 24, 26 is connected to the potential of the intermediate circuit voltage U_{ZK}. Accordingly, when the semiconductor switch 44 is opened and the semiconductor switch 46 is closed, the phase U, V, W is contacted with the ground potential U_{G}. As a result, it is possible by means of the PWM control to load each phase winding U, V, W with two different voltage levels.

In FIG. 3, a single bridge module 20 is illustrated in a simplified manner. In this exemplary embodiment, the semiconductor switches 44 and 46 are realized as MOSFETs (metal oxide semiconductor field effect transistors) which in each case switch by means of the PWM control between an active state and an off state in a clocked manner. To this end, the respective gate terminals are led to corresponding control voltage inputs 52, 54, by means of which the signals of the PWM control of the controller 42 are transmitted.

FIG. 4 shows an equivalent circuit diagram for the current source 8. In operation, the battery 10 generates a battery power P_{Bat} (FIG. 5), a battery voltage U_{Bat} and also a corresponding battery current I_{Bat} for operating the power converter 6. In FIG. 4, the internal resistance of the battery 10 is illustrated as an ohmic resistor 56 and an inherent inductance of the battery 10 is illustrated as an inductor 58. A shunt resistor 60 is connected in the return line 12b.

Depending on the switching states of the (power) semiconductor switches 44, 46, the phase current I_{U}, I_{V}, I_{W} flows via the shunt resistor 60. The voltage drop because of the shunt resistor 60 is amplified and evaluated. With measurements and the level of knowledge of the switching states of the semiconductor switches 44, 46, the phase currents I_{U}, I_{V}, I_{W} are reconstructed by the controller 42. Other measuring methods can also be used for determining the motor currents (e.g. direct phase current measurement). Together with the measured and/or calculated phase voltages (U_{U}, U_{V}, U_{W}) the phase voltages (U_{U}, U_{V}, U_{W}) and the phase currents I_{U}, I_{V}, I_{W} are available to the controller 42.

In the exemplary embodiment of FIG. 1, the motor current is detected by means of a current measuring instrument 62, for example by means of the shunt resistor 60 and carried to the controller 42. On the basis of motor variables, in particular on the basis of the detected phase currents I_{U}, I_{V}, I_{W} and calculated phase voltages U_{U}, U_{V}, U_{W}, and also on the basis of other variables (e.g. motor resistance, motor inductance, duty cycle of the PWM voltage), the controller 42 determines a rotational variable θ, ω, that is to say calculates or estimates the motor position (rotor position) θ and/or the (rotor) speed ω. In particular, an electric motor position θₑₗ or an electrical frequency/speed ωₑₗ is calculated or estimated.

FIG. 5 here shows a block diagram for operation of the electric machine 2 according to the method. The open-loop and/or closed-loop control of the electric motor 4 here takes place in a d-q reference system with a d axis and a q axis.

According to the method, a set-point current value I_{dset} and I_{qset} are specified for the set-point current along the d and q axes for a control unit 64 of the controller 42. By means of a field-oriented control, the control unit 64 determines corresponding control signals U_{dFOC} and U_{qFOC} for the voltage for controlling the electric motor 4.

At the start of the operation, that is to say for example in the case of start-up from the standstill of the electric motor 4, the back EMF is not sufficient to generate a satisfactory voltage 40, so the measured current signals of the current measuring instrument 62 are not sufficient for determining the motor position θₑₗ. As a consequence, the set-point current values I_{dset} and I_{qset} for the control unit 64 cannot be determined on the basis of the measured current signals. At the start of the method or the operation, the motor position θₑₗ is therefore estimated by the controller and the set-point current values I_{dset} and I_{qset} for the control unit 64 are determined therefrom.

To check and adapt the position estimation, a test signal or test pulse U_{dTest} is generated by a compensation unit 66, by means of which test signal or test pulse a deviation between an actual motor position and the estimated motor position can be determined. This test signal U_{dTest} is fed into the d axis of the electric motor 4, in particular the test signal U_{dTest} is added to the control signal U_{dFOC}.

In addition to the test signal U_{dTest}, the compensation unit 66 generates a compensation signal U_{qComp} which is fed into the q axis of the electric motor 4. In particular, the compensation signal U_{qComp} is added to the control signal U_{qFOC}. The compensation signal U_{qComp} is determined on the basis of the test signal U_{dTest} here by means of a calculation 68 in such a manner that when the compensation signal U_{qComp} is fed into the q axis, a torque change of the electric motor 4 owing to the test signal U_{dTest} is reduced or compensated.

The control signals U_{d}′, U_{q}′ modified using the test signal U_{dTest} and the compensation signal U_{qComp} are converted by a PWM driver, which is not shown in any more detail, to the corresponding PWM signals for controlling the bridge circuit 16.

Preferably, the torque change of the electric motor 4 owing to the test signal U_{dTest} is reduced as completely as possible by the compensation signal U_{qComp}, so that a particularly quiet start of the electric machine 2 is enabled.

The calculation 68 for determining the compensation signal U_{qComp} is based here on a motor model for the electric motor 4. Preferably, the calculation 68 is based on the d-q motor model of the electric motor 4, which is illustrated in FIG. 5, for the motor-side conversion of the modified control signals U_{d}′, U_{q}′ to the motor currents I_{q} and I_{d}.

In the following, the d-q motor model is explained in more detail with reference to FIG. 5.

The d model for converting the modified control signal U_{d}′ to the motor current I_{d} comprises a coil portion and an ohmic portion as well as a reactance portion.

The coil portion is modeled by an amplification 70 with the factor 1/L_{d}, wherein L_{d} is the inductance value of the inductor 30 along the d axis, and by an integrator 72.

The ohmic portion corresponds to the voltage loss owing to the ohmic resistor 32. The ohmic portion is realized as negative feedback with an amplification 74 with the factor R, wherein R is the ohmic resistance 32 of the electric motor 4 or the stator.

The reactance portion corresponds to the portion induced owing to the rotor rotation owing to the motor current I_{q}. For the reactance portion, a value for the motor speed or rotor frequency ωₑₗ is determined, for example estimated, by the controller. The motor speed ωₑₗ is multiplied by the motor current I_{q}, which is determined by the q model that is explained below, and by the factor L_{q}, by means of an amplification 76, wherein L_{q} is the inductance value of the inductor 30 along the q axis. The reactance portion is here added to the control value U_{d}′.

The q model for converting the modified control signal U_{q}′ to the motor current I_{q} comprises a coil portion and an ohmic portion as well as a reactance portion and an induced portion.

The coil portion is modeled by an amplification 78 with the factor 1/L_{q} and by an integrator 80.

The ohmic portion is realized as negative feedback with an amplification 82 with the resistance value R.

For the reactance portion, the motor speed ωₑₗ is multiplied by the motor current I_{d}, which is determined by the d model, and by the factor L_{d}, by means of an amplification 84. The reactance portion is subtracted from the control value U_{q}′.

The induced portion is modeled as product of the motor speed ωₑₗ with the magnetic flux Ψ, wherein the product is realized as an amplification 86 with the factor PsiM and wherein PSiM corresponds to the magnetic flux Ψ. The induced portion is subtracted from the control value U_{q}′.

For example, the compensation signal U_{qComp} is determined by means of the calculation 68 on the basis of the formula

$$Δ {u}_{q} = \frac{{ω}_{el} {L}_{d} - k * ( {R}_{S} + {L}_{q} s )}{k * {ω}_{el} {L}_{q} + ( {R}_{S} + {L}_{d} s )} Δ {u}_{d}$$

Here, Δu_{q} is the compensation signal U_{qComp}, Δu_{d} is the test signal U_{dTest}, ωₑₗ is the motor speed, L_{d} and L_{q} are the inductance values of the inductor 30 along the d and q axes respectively, R_{S} is the ohmic resistance of the ohmic resistor 32, s is the Laplace transformation parameter, and k is a compensation factor.

To reduce the computation outlay, a simplified calculation 68 can also be used, in which at least one approximation is carried out.

For small rotor frequencies (ωₑₗ~0 kHz), as exist for example in the case of start-up from standstill, the above formula can be approximated with

$$Δ {u}_{q} ≅ \frac{- k * ( {R}_{S} + {L}_{q} s )}{( {R}_{S} + {L}_{f} s )} Δ {u}_{d}$$

If R_{S} can additionally be disregarded, the following results:

$$Δ {u}_{q} ≅ \frac{- k * {L}_{q}}{{L}_{d}} Δ {u}_{d}$$

If however, R_{S} but not ωₑₗ can be disregarded, the following results:

$$Δ {u}_{q} ≅ \frac{{ω}_{el} {L}_{d} - k * {L}_{q} s}{k * {ω}_{el} {L}_{q} + {L}_{d} s} Δ {u}_{d}$$

wherein Δu_{q} is the compensation signal U_{qComp}, Δu_{d} is the test signal U_{dTest}, ωₑₗ is the motor speed, L_{d} and L_{q} are the inductance values of the inductor 30 along the d and q axes respectively, s is the Laplace transformation parameter, and k is the compensation factor.

The compensation factor k is determined in particular on the basis of the formula

$$\frac{Δ {i}_{q}}{Δ {i}_{d}} = - \frac{( {L}_{d} - {L}_{q} ) {i}_{q}}{Ψ + ( {L}_{d} - {L}_{q} ) {i}_{d}} = k$$

wherein Ψ is the magnetic flux, i_{q} and i_{d} are the motor currents I_{q} and I_{d}, and Δi_{q} and Δi_{d} are the resultant current changes due to the test signal U_{dTest} and the compensation signal U_{qComp} along the d and q axes. To simplify the calculation 68 and therefore to reduce the computation outlay, a simplified proportionality calculation can be used. The above proportionality calculation can be approximated for large magnetic fluxes Ψ>>(L_{d}−L_{q})i_{d} using

$$k ≅ - \frac{( {L}_{d} - {L}_{q} )}{Ψ} {i}_{q}$$

For a particularly resource-saving determination of the compensation signal, which has reduced computation outlay, the preceding approximations can be combined with one another. Thus, for Ψ>>(L_{d}−L_{q})i_{d} with a simultaneous disregarding of the influence of R_{S} and ωₑₗ:

$$Δ {u}_{q} \underline{≃} \frac{( {L}_{d} - {L}_{q} ) * {L}_{q}}{Ψ * {L}_{d}} Δ {u}_{d}$$

wherein Δu_{q} is the compensation signal U_{qComp}, Δu_{d} is the test signal U_{dTest}, Ψ is the magnetic flux, and L_{d}/L_{q} is the inductance value of the inductor 30 along the d/q axis.

A sinus voltage with a constant frequency can for example be used as test signal U_{dTest}. In the calculation 68, the Laplace transformation parameter s can therefore be replaced by jω_{ud}, wherein j is the imaginary unit, and ω_{ud} is the frequency of the test signal. The following therefore results

$$Δ {u}_{q} = \frac{{ω}_{el} {L}_{d} - k * ( {R}_{S} + {L}_{q} j {ω}_{Ud} )}{k * {ω}_{el} {L}_{q} + ( {R}_{S} + {L}_{d} j {ω}_{Ud} )} Δ {u}_{d}$$

The simplifications Ψ>>(L_{d}−L_{q})i_{d} and/or the disregarding of R_{S} and ωₑₗ can here also be used to reduce the computation outlay.

The motor response to the test signal U_{dTest} and the compensation signal U_{qComp}, that is to say the motor currents I_{q} and I_{d} are detected by the current measuring instrument 62 and used for determining the motor position or for determining the deviation between the estimated and actual motor position. This deviation is controlled in a closed-loop manner using the controller 42 in such a manner that it is as small as possible so that the estimated and actual motor position match to the greatest extent possible.

The claimed invention is not limited to the previously described exemplary embodiments. Rather, different variants of the invention may also be deduced from this by a person skilled in the art in the context of the disclosed claims without departing from the subject matter of the claimed invention. In particular, all of the individual features described in connection with the various exemplary embodiments in the context of the disclosed claims can further also be combined in a different way without departing from the subject matter of the claimed invention.

### LIST OF REFERENCE SIGNS

2 Machine
4 Electric motor
6 Power converter
8 Current source
10 Battery
12 Intermediate circuit
12a Outgoing line
12b Return line
14 Intermediate-circuit capacitor
16 Bridge circuit
18 Star connection
20 Bridge module
22, 24, 26 Phase end
28 Star point
30 Inductor
32 Resistor
34, 36, 38 Voltage drop
40 Voltage
42 Controller
44, 46 Semiconductor switch
48, 50 Potential terminal
52, 54 Control voltage input
56 Resistor
58 Inductor
60 Shunt resistor
62 Current measuring instrument
64 Control unit
66 Compensation unit
70 Amplification
72 Integrator
74, 76, 78 Amplification
80 Integrator
82, 84, 86 Amplification
U, V, W Phase/phase winding
I_{U}, I_{V}, I_{W} Phase current/output current
I_{E} Input current
U_{ZK} Intermediate circuit voltage
U_{G} Ground potential
I_{Bat} Battery current
U_{Bat} Battery voltage
ωₑₗ (Electrical) frequency/motor speed
I_{dset}, I_{qset} Current set-point value
U_{dFOC}, U_{qFOC} Control signal
U_{dTest} Test signal
U_{qComp} Compensation signal
I_{q}, I_{d} Motor current
U_{d}′, U_{q}′ Control signal

1-11. (canceled)

12. A method for operating an electric machine having a brushless electric motor with a stator, a rotor, and a control unit for sensorless field-oriented open-loop and/or closed-loop control of the brushless electric motor in a d/q reference system with a d axis and with a q axis, which is fixed with respect to the rotor, which comprises the steps of:
controlling the brushless electric motor in an open-loop and/or closed-loop manner on a basis of an estimated motor position at a start of operation;
generating a test signal for determining a deviation between an actual motor position and the estimated motor position;
feeding the test signal into the d axis;
determining a compensation signal on a basis of the test signal such that when the compensation signal is fed into the q axis, a torque change of the brushless electric motor owing to the test signal is reduced; and
feeding the compensation signal into the q axis.

13. The method according to claim 12, which further comprises reducing completely the torque change of the brushless electric motor owing to the test signal by the compensation signal.

14. The method according to claim 12, which further comprises detecting a motor response to the test signal and the compensation signal and using the motor response for determining a motor position.

15. The method according to claim 12, which further comprises determining the compensation signal on a basis of a formula
$$Δ {u}_{q} = \frac{{ω}_{el} {L}_{d} - k * ( {R}_{S} + {L}_{q} s )}{k * {ω}_{el} {L}_{q} + ( {R}_{S} + {L}_{d} s )} Δ {u}_{d}$$
wherein:
Δu_{q} is the compensation signal;
Δu_{d} is the test signal;
ωₑₗ is a frequency of the rotor;
L_{d} is an inductance value of the stator along the d axis;
L_{q} is an inductance value of the stator along the q axis;
R_{S} is an ohmic resistance of the stator;
s is a Laplace transformation parameter; and
k is a compensation factor.

16. The method according to claim 12, which further comprises determining the compensation signal on a basis of a formula
$$Δ {u}_{q} ≅ \frac{- k * ( {R}_{S} + {L}_{q} s )}{( {R}_{S} + {L}_{d} s )} Δ {u}_{d}$$
wherein:
Δu_{q} is the compensation signal;
Δu_{d} is the test signal;
R_{S} is an ohmic resistance of the stator;
L_{d} is an inductance value of the stator along the d axis;
L_{q} is an inductance value of the stator along the q axis;
s is a Laplace transformation parameter; and
k is a compensation factor.

17. The method according to claim 12, which further comprises determining the compensation signal on a basis of a formula
$$Δ {u}_{q} ≅ \frac{( {L}_{d} - {L}_{q} ) * {L}_{q}}{Ψ * {L}_{d}} Δ {u}_{d}$$
wherein:
Δu_{q} is the compensation signal;
Δu_{d} is the test signal;
Ψ is a magnetic flux;
L_{d} is an inductance value of the stator along the d axis; and
L_{q} is an inductance value of the stator along the q axis.

18. The method according to claim 15, which further comprises determining the compensation factor k is determined on a basis of a formula
$$\frac{Δ {i}_{q}}{Δ {i}_{d}} = - \frac{( {L}_{d} - {L}_{q} ) {i}_{q}}{Ψ + ( {L}_{d} - {L}_{q} ) {i}_{d}} = k$$
wherein:
i_{q} is a motor current along the q axis;
i_{d} is a motor current along the d axis;
Δi_{q} is a resultant current change due to the compensation signal along the q axis;
Δi_{d} is a resultant current change due to the test signal along the d axis;
Ψ is a magnetic flux;
L_{d} is the inductance value of the stator along the d axis; and
L_{q} is the inductance value of the stator along the q axis.

19. The method according to claim 15, which further comprises determining the compensation factor k on a basis of a formula
$$k ≅ - \frac{( {L}_{d} - {L}_{q} )}{Ψ} {i}_{q}$$
wherein:
i_{q} is a motor current along the q axis;
Ψ is a magnetic flux;
L_{d} is the inductance value of the stator along the d axis; and
L_{q} is the inductance value of the stator along the q axis.

20. The method according to claim 12, which further comprises providing a sinus voltage with a constant frequency as the test signal.

21. An electric machine, comprising:
a brushless electric motor with a rotor and a stator;
a first controller for sensorless field-oriented open-loop and/or closed-loop control of said brushless electric motor; and
a second controller for carrying out the method according to claim 12.

22. A non-transitory data medium carrying computer executable instructions which when executed by a computer carries out the method according to claim 12.
